(19) United States
(12) Patent Application Publication
(10) Pub. No.: US 2026/0063671 A1
(43) Pub. Date: Mar. 5, 2026

(54) POWER SUPPLY PROBE WITH POLARITY SAFEGUARD

(71) Applicant: Innova Electronics Corporation, Irvine, CA (US)

(72) Inventors: Hoang Nguyen, Ho Chi Minh City (VN); Ly Bach, Ho Chi Minh City (VN); Phuong Pham, Fountain Valley, CA (US); Tai Mai, Ho Chi Minh City (VN)

(21) Appl. No.: 18/818,207

(22) Filed: Aug. 28, 2024

(51) Int. Cl. G01R 1/28; G01R 1/067; G01R 31/00

(52) U.S. Cl. CPC G01R 1/28; G01R 1/06788; G01R 31/006

(57) ABSTRACT

A system and method provides for safeguarded selection of a polarity for selected application of power or ground to a test circuit via a circuit tester test probe. A positive polarity selection switch is aligned with a negative polarity selection switch on a probe surface. A virtual switch indicia is shown on a probe display with an actuation axis of the virtual switch oriented to correspond to relative alignment of the polarity switches. Pressing the positive polarity switch places the virtual switch in a first position indicating a positive probe polarity selection and pressing the negative polarity switch places the virtual switch in a second position indicating a negative probe polarity selection. Additional polarity selection indicia are generated to reinforce user recognition of a selected polarity to avoid circuit or probe damage.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

### 1. Technical Field

The present disclosure relates generally to electrical testers. The disclosure relates more particularly to circuit testers that include a function to provide DC power via a directable voltage polarity while providing clear and accessible information to the user.

### 2. Description of the Related Art

Electrical components, like any device, are subject to failure. A circuit tester is an electrical tool used to evaluate the functionality, integrity, and safety of electrical circuits and components. It helps identify various conditions within a circuit, such as the presence of voltage, continuity, polarity, and current flow. Circuit testers come in various forms, including simple devices like continuity testers and multimeters, as well as more advanced tools like power probes and oscilloscopes. They are essential for diagnosing electrical issues, verifying proper circuit operation, and ensuring that electrical systems are safe and comply with specified standards.

An automotive circuit tester is a specialized diagnostic tool used by mechanics and automotive technicians to troubleshoot and diagnose electrical issues in vehicles. Testing devices may include multiple functions in connection with testing and analysis of vehicle electrical systems. Devices may generate or measure both AC and DC voltage levels, which is needed for checking battery voltage, alternator output, and verifying power supply to various components. Devices may test for continuity in a circuit, helping to determine if wires, fuses, and connections are intact and unbroken, usually signaled by a beep or light indicator.

Testers may identify a polarity of a circuit, distinguishing between positive and negative connections, which is needed for ensuring proper connections, especially with polarity-sensitive components. Additionally, it can check for proper grounding in the vehicle's electrical system, necessary for the correct operation of many electrical components. Testers can apply power directly to electrical components such as lights, motors, solenoids, and relays to verify their operation, allowing technicians to test components without using the vehicle's controls.

More advanced models can detect short circuits and provide audio or visual alerts, helping to identify and locate shorted wires or components. A tester may also allow for quick testing of fuses to determine if they are blown without removing them from their holders.

Testers may include a probe tip that allows easy access to small and hard-to-reach areas in the vehicle's electrical system. Testers may also include a digital display to show voltage readings, polarity indicators, and other diagnostic information. A tester is often powered by the vehicle's battery or an internal battery, and when testing or activating components, it can draw power from these sources.

For example, when testing battery voltage, when one connects the tester's probes to the positive and negative terminals of the battery, the display will show the present voltage, helping assess the battery's health. To check a conductor for continuity, one connects a ground clip, such as an alligator clip, to one end of a conductor and a probe to the other end. If the conductor is intact, the tester will indicate continuity. To activate a light, one connects the tester's probe to a terminal of a light bulb and the alligator clip to ground, and then applies power using the tester. If the light illuminates, it is functioning correctly. When identifying a short circuit, one probes different points in a circuit while monitoring the tester's alerts, and if a short is detected, the tester will provide a warning, indicating the presence of a short circuit.

Circuitry of an automotive probe circuit tester operates through a combination of components and principles that enable it to perform various diagnostic functions, examples of which follow.

### Voltage Measurement

To measure voltage, the circuit tester uses a high-impedance voltmeter circuit. When the probes are connected to a circuit, the voltmeter measures the potential difference between the positive and negative probes. The high impedance ensures that the tester does not significantly load the circuit, thereby providing an accurate voltage reading without affecting the circuit's operation. The measured voltage is then displayed on a digital readout or analog meter.

### Continuity Testing

For continuity testing, the tester includes a low-voltage power source, such as a small battery, and a resistor to limit current. When the probes are placed across a wire or component, the circuit is completed if there is continuity, allowing current to flow through the device under test. This current flow is detected by the tester's internal circuitry, which activates an indicator, such as an LED or a buzzer, to signal continuity.

### Polarity Identification

The tester may use a diode bridge or similar circuitry to determine the polarity of the voltage present at the probes. When connected to a circuit, the tester checks the direction of current flow to identify the positive and negative terminals. The result is then indicated through polarity-specific LEDs or a display, helping the user correctly identify the positive and negative sides of the circuit.

### Ground Testing

For ground testing, the tester checks the resistance between the probe and the vehicle's chassis ground. A good ground connection will show low resistance, while a poor ground will show higher resistance. The tester's circuitry measures this resistance and provides feedback through a display or indicator light.

### Component Activation

To activate components which have been separated from the electrica system, the tester can apply a controlled voltage and current from its internal power source. When a probe is connected to a component, such as a light or motor, the tester sends a small amount of power through the component. If the component operates correctly, it indicates that the component is functional. The circuitry ensures that the applied voltage and current are within safe limits to avoid damaging the component.

Testers, particularly those used in the automative industry, can selectively provide a positive voltage or a negative voltage on a tester probe. Both are useful in various testing scenarios.

Using a tester with the probe set to ground can be useful in an automotive setting for a variety of diagnostic tasks. When the probe is set to ground, it helps verify the integrity of ground connections, check for continuity, and diagnose issues related to grounding in the vehicle's electrical system.

One use of a ground probe is to verify the quality and integrity of ground connections throughout the vehicle. A poor ground connection can cause numerous electrical issues. To verify ground points, one locates ground points in a vehicle, such as the chassis, engine block, and grounding straps and attaches the tester's ground clip to a known good ground point on the vehicle's chassis, and then touches the probe to various ground points and components. The tester will indicate if there is a good ground connection by showing continuity or a low resistance reading. A tester with a ground probe is useful for checking the continuity of wires, connectors, and components to ensure there are no breaks or faults. Set the tester to measure continuity, connect the ground clip to a known good ground, and touch the probe to different points in the circuit. A continuous path will give an indication that the circuit is complete.

Ground faults can cause erratic behavior in automotive electrical systems. Using a ground probe helps identify these faults. One can isolate the circuit by turning off the power to the circuit you are testing to avoid false readings and potential damage. One attaches the tester's ground clip to the vehicle's chassis and touches the probe to various points in the circuit, looking for unexpected readings or lack of continuity, which can indicate a ground fault.

Many sensors in a vehicle use ground as a reference point. Testing these sensors with a ground probe ensures they are operating correctly. One identifies a sensor for testing, such as an oxygen sensor or a temperature sensor, and attaches the ground clip to a known good ground. Touching the probe to the sensor's output terminal while the sensor is operating and comparing the reading to the expected values to can ensure proper function.

By way of further example, there may be an issue with headlights that flicker intermittently. A common cause could be a poor ground connection. Attaching the ground level clip to a known good ground on the chassis and touching the probe to the ground wire of the headlight circuit tests for continuity. If the tester indicates continuity, the ground connection is good. If not, the ground wire and connection point can be inspected for corrosion, looseness, or damage.

In another example, one may suspect a break in a wiring harness is causing a component to malfunction. Attaching the ground clip to a known good ground and touching the probe to both ends of the suspect wire will indicate whether the wire is continuous. A lack of continuity suggests a break or fault in the wire.

A design of the circuit tester may include a microcontroller or CPU that manages the different testing functions and processes the input from the probes. A voltage regulator may also be included to stabilize operation of the internal electronics by providing a consistent voltage supply. A display or indicators may be included to show the test results, such as voltage readings, continuity status, and polarity.

A positive voltage probe can be used test a power supply to various components in the vehicle. For instance, when diagnosing an issue with the fuel injectors, the positive probe can be used to check if the injectors are receiving the correct voltage. One may connect the ground clip to a known good ground and touch the positive probe to the positive terminal of the fuel injector to power it. If the injector receives the proper voltage (e.g., 12V), it should function correctly. If not, this could indicate a problem with the power supply circuit.

Actuators such as solenoids, relays, and motors require a specific voltage to operate. To test these components, the positive probe can be used to apply the required voltage directly. For example, to test a relay, one might connect the ground clip to a good ground, and touch the positive probe to the relay's input terminal. Applying the correct voltage will activate the relay, allowing one to verify its functionality. If the relay does not activate, it may be faulty.

Many automotive sensors provide an output signal that can be checked with a positive voltage probe. For instance, testing a throttle position sensor (TPS) involves applying a positive voltage to its signal wire while monitoring the output. One may connect the ground clip to a known ground and touch the positive probe to the sensor's signal wire. The output voltage should vary smoothly as the throttle is opened and closed. Any irregularities in the output can indicate a faulty sensor.

Automotive lighting circuits, such as headlights, brake lights, and turn signals, can be tested using a positive voltage probe. To test a headlight, one can connect the ground clip to a known ground and touch the positive probe to the power terminal of the headlight. If the headlight illuminates, it is receiving the correct voltage and functioning properly. If not, this may indicate a problem with the power supply or the headlight itself.

The vehicle's charging system, including the alternator and voltage regulator, can be tested using a positive voltage probe. To check the alternator's output, one can touch the positive probe to the alternator's output terminal. The voltage reading should match the expected charging voltage (typically around 13.8 to 14.4 volts). If the reading is outside this range, there may be an issue with the alternator or voltage regulator.

A positive voltage probe can be used to test the integrity of electrical connectors and wiring. For example, if there is a suspected break in a wire, one can touch the positive probe to various points along the wire. If the wire is intact, the voltage reading should be consistent along its length. A drop in voltage or no reading at all can indicate a break or fault in the wiring.

### BRIEF SUMMARY

In accordance with an example embodiment of the present disclosure, a power supply probe for supplying test power or ground during circuit testing is provided with a voltage polarity safeguard. A user interface has a plurality of control switches, including a negative polarity selection switch and a positive polarity selection switch, and an image display. A power input receives electrical power from an associated power source. A processor and associated memory, function to receive a polarity selection signal from user corresponding to an engagement of one of the negative polarity switch or the positive polarity switch. The processor then initiates application of a probe voltage having a selected polarity associated with a received polarity selection signal on a probe tip while showing an image corresponding to a switch, such as a rocker switch, on the display. The image shows the rocker switch in a first or second position in accordance with a value of the selected polarity.

In accordance with another example embodiment of the present disclosure, the user interface includes a directional pad, wherein the negative polarity switch and the positive polarity switch are on opposed directional controls on the d-pad.

In accordance with another example embodiment of the present disclosure, an alignment of the opposed directional controls corresponds to an alignment of an actuation axis of the rocker switch image.

In accordance with another example embodiment of the present disclosure, the processor terminates voltage application on the probe tip when no polarity selection switch is engaged.

In accordance with another example embodiment of the present disclosure, the processor shows selectable indicia on the display corresponding to a plurality of different voltage levels and receives user navigation input via the d-pad to a selected one of the selectable indica. The processor then initiates the application of the probe voltage with a voltage level corresponding to the selected indicia.

In accordance with another example embodiment of the present disclosure, the processor limits setting a probe voltage level to when the selected polarity is positive.

In accordance with another example embodiment of the present disclosure, the processor sets a probe tip to a neutral level when the positive polarity selection switch and the negative polarity selection switch are engaged concurrently. The neutral level can allows a probe to determine polarity at a test sight.

### BRIEF DESCRIPTION OF THE DRAWINGS

These and other features and advantages of the various embodiments disclosed herein will be better understood with respect to the following description and drawings, in which:

FIG. 1 illustrates an example embodiment of a circuit tester system for a power supplying probe with a polarity safeguard;

FIG. 2 illustrates a flowchart for an example embodiment of a circuit tester for a power supplying probe with a polarity safeguard;

FIG. 3 illustrates example embodiments of a circuit tester having a selectable a circuit tester for a power supplying probe with a polarity safeguard;

FIG. 4 illustrates a circuit diagram for an example embodiment of a circuit tester for a power supplying probe with a polarity safeguard;

FIG. 5 illustrates another example embodiment of a circuit tester for supplying a power supplying probe with a polarity safeguard; and

FIG. 6 is a flowchart suitable for operation of the microcontroller of FIG. 5.

### DETAILED DESCRIPTION

The detailed description set forth below in connection with the appended drawings is intended as a description of certain embodiments of a vehicle diagnostic system and related method, and is not intended to represent the only forms that may be developed or utilized. The description sets forth the various structure and/or functions in connection with the illustrated embodiments, but it is to be understood, however, that the same or equivalent structure and/or functions may be accomplished by different embodiments that are also intended to be encompassed within the scope of the present disclosure. It is further understood that the use of relational terms such as first and second, and the like are used solely to distinguish one entity from another without necessarily requiring or implying any actual such relationship or order between such entities.

As noted earlier, one valuable aspect of a test probe is to selectively supply a positive voltage or a negative voltage to a circuit for testing.

Negative voltages, typically grounded in an automotive tester, provide for useful testing in many situations. Using a tester with the probe set to ground can be extremely useful in an automotive setting for a variety of diagnostic tasks. When the probe is set to ground, it helps verify the integrity of ground connections, check for continuity, and diagnose issues related to grounding in the vehicle's electrical system.

A poor ground connection can cause numerous electrical issues. Ground faults can cause erratic behavior in automotive electrical systems. Using a ground probe helps identify these faults. Many sensors in a vehicle use ground as a reference point. Testing these sensors with a ground probe ensures they are operating correctly. Identify the sensor you need to test, such as an oxygen sensor or a temperature sensor, and attach the ground clip to a known good ground. Touch the probe to the sensor's output terminal while the sensor is operating and compare the reading to the expected values to ensure proper function.

Testers can use a rocker switch as a user interface for controlling the polarity of a test probe. Using a rocker switch to select polarity for an automotive probe can offer several advantages, particularly when an operator needs to frequently alternate between positive and negative voltage during a sequence of tests. A rocker switch, such as a Single Pole Double Throw (SPDT) provides a straightforward and intuitive interface, allowing the operator to change polarity by simply rocking the switch back and forth with two fingers. This ease of use is beneficial in complex testing scenarios where quick and frequent polarity changes are necessary.

Rocker switches can be operated quickly, enabling the operator to switch between positive and negative voltage almost instantaneously, thus speeding up the testing process. The tactile feedback from the switch helps confirm the polarity change without requiring the operator to look at the switch, which is especially useful when their attention is focused on the circuit being tested. Another feature of rocker switches is their inherent inability to provide for simultaneous selection of both positive and negative polarity. Activating both selections simultaneously could be disastrous as this would create a direct short circuit. This is because one switch would connect the probe tip to the positive voltage while the other connects it to the negative voltage, effectively creating a direct connection between the positive and negative terminals. This could result in a high current flow through the circuit, potentially damaging the tester, damaging the power source, blowing a fuse or tripping a circuit breaker.

While using a rocker switch for polarity selection has advantages, a more versatile interface for probes having increased functionality and controllability can be provided by use of a directional pad. A directional pad interface, commonly known as a d-pad, is a user input device featuring a flat, typically cross-shaped button with four directional controls: up, down, left, and right. It is designed to provide intuitive and precise navigation or control over a system or device. The d-pad can be used in various electronic devices, such as remote controls, gaming controllers, and certain handheld gadgets. It allows for input in four main directions, and some d-pads may support diagonal inputs by pressing two adjacent directions simultaneously.

D-pads typically provide tactile feedback, making it easier for users to sense when they have pressed a button. This tactile response enhances the user experience by providing a more responsive feel. The compact design of a d-pad consolidates multiple directional controls into a single interface, saving space and allowing for a more streamlined and ergonomic layout. While primarily used for navigation, d-pads can be configured for various functions, such as adjusting settings, controlling movement in games, or selecting options in a menu.

The straightforward layout of a d-pad makes it easy to use, even for those unfamiliar with a specific device. They allow for accurate directional inputs, which is particularly important in applications requiring fine control. D-pads are typically robust and can withstand repeated use, making them suitable for high-usage environments. Additionally, they can be programmed for various functions beyond simple navigation, making them a flexible interface option.

In an example embodiment herein, a probe for selectively supplying a positive voltage or a negative voltage (or a ground state) to a probe is controlled by a d-pad. While d-pads provide a more versatile user interface and can be used effectively in conjunction with display scrolling or navigation, conventional d-pads may suffer from disadvantages in probe voltage application situations. Tactile user feedback is substantially different than that of a rocker switch polarity selector. Also, there is a possibility that an incorrect selection is made on the d-pad or that two controls are depressed concurrently, which is not possible on a rocker switch. This can be particularly problematic when a probe is used an automotive environment.

Applying the wrong polarity during automotive circuit testing can lead to several potential problems, some of which can be quite serious. Many automotive components, especially electronic ones, are polarity-sensitive. Applying the wrong polarity can cause immediate and often irreversible damage to components such as sensors, control modules, and actuators. For example, diodes, transistors, and integrated circuits can fail when subjected to reverse polarity.

Automotive circuits are protected by fuses designed to blow in the event of an overcurrent situation. Applying the wrong polarity can create a short circuit or overload condition, leading to blown fuses. This not only interrupts the functionality of the circuit but also requires troubleshooting to replace the fuse and identify the root cause of the issue. Incorrect polarity can cause short circuits within the vehicle's wiring. This can generate excessive heat, potentially melting insulation and causing wires to fuse together. In severe cases, this might lead to fire hazards or extensive damage to the wiring harness.

Automotive systems such as the engine control unit (ECU), anti-lock braking system (ABS), and infotainment systems rely on correct polarity for proper operation. Applying the wrong polarity can cause these systems to malfunction or shut down, leading to poor vehicle performance, safety risks, and potential regulatory compliance issues. Many modern vehicles use electronic control units that store critical data, including diagnostic trouble codes and configuration settings. Incorrect polarity can corrupt this data or even erase it, complicating the diagnostic process and potentially leading to incorrect repairs.

Applying reverse polarity to the battery or charging system can cause significant damage. For example, it can damage the alternator, voltage regulator, or even the battery itself. This can lead to charging system failure and prevent the vehicle from starting or running properly. Incorrect polarity can pose serious safety risks to technicians. Sparks, arcing, and electric shocks can occur, especially in high-voltage systems found in hybrid or electric vehicles. This can result in personal injury or damage to diagnostic equipment.

The damage caused by applying the wrong polarity often requires replacement of expensive components and extensive labor to trace and repair damaged wiring. This can significantly increase repair costs and time. Incorrect polarity can void warranties on certain components. Manufacturers typically specify correct polarity for installation and testing, and failure to adhere to these guidelines can result in denied warranty claims.

Incorrect polarity can lead to confusing and misleading diagnostic results. For example, sensors might provide erroneous readings or control units might log incorrect fault codes. This can make it difficult to accurately diagnose and repair issues, leading to further complications and delays. In summary, applying the wrong polarity during automotive circuit testing can cause a range of problems, including component damage, blown fuses, short circuits, system malfunctions, data loss, battery and charging system issues, safety hazards, increased repair costs, warranty issues, and diagnostic confusion. It is crucial to ensure correct polarity during testing to avoid these potential issues and ensure accurate and safe diagnostics and repairs.

Example embodiments herein provide a testing system that includes a function of application of positive or negative voltage to a test circuit that uses a d-pad interface while simultaneously providing a user experience associated with familiar rocker switch polarity selection feedback to maximize user comfort and minimize opportunity for application of improper voltage polarity during testing operations.

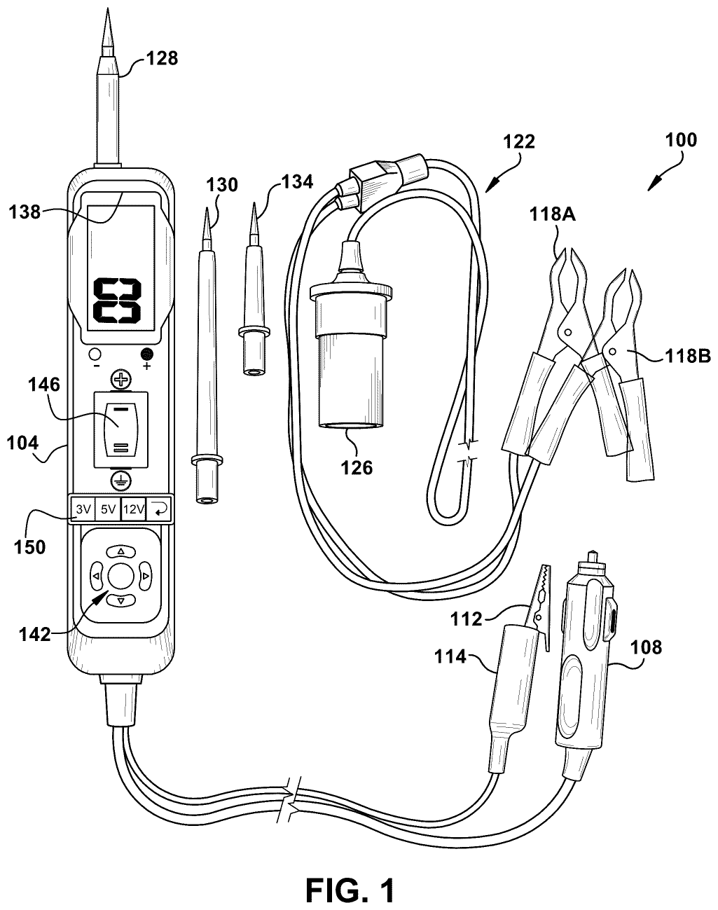

Referring to the associated drawings, FIG. 1 illustrates an example embodiment of a circuit tester system 100 for a power supplying probe with a polarity safeguard that includes a handheld base unit 104. The base unit is suitably powered by automotive power plug 108, configured to be received into a corresponding automotive power outlet (not shown). While the power plug provides a connection to both positive and negative of the vehicle power system, a more robust and reliable connection to ground is achieved via connection of alligator clip 112 directly to a vehicle frame. Alligator clip 112 is suitably disposed within a cover 114. In the event that a vehicle lighter socket is unavailable or inconveniently located, alternative power can be obtained by a direct battery or battery/frame connection via jumper cable clips 118A and 118B of power cable 122. A distal end of power cable 122 relative to the jumper cable clips suitably includes automotive power outlet socket 126 configured to receive power plug 108. The testing system includes one or more interchangeable conductive test probes, such probe 128, shown affixed to base unit 104, and alternative probes such as relatively long test probe 130 and a relatively short test probe 134, each of which can be used by electrical connection to the tester.

Base unit 104 includes a user interface comprising display 138 and d-pad 142. Display 138 shows switch indicia 146 as a rocker switch with which an indicator of a current probe polarity is provided as will be detailed below. Display 138 further shows a navigable, user selectable probe tip voltage level selections 150 operable in conjunction with d-pad 142 when a probe tip is set to a positive polarity. In example embodiments herein, opposed d-pad direction switches, such as the up switch and the down switch, are used to select positive or negative tip polarity. An activation axis of the virtual switch is aligned in a vertical direction on the display. A user toggling between the up arrow polarity selection and the down arrow polarity selection will see an image of a top portion of the virtual switch being depressed and an image of a bottom portion of the virtual switch being depressed, respectively. The user is thus provided visual feedback of their selected polarity via the virtual switch. Although up and down directional switches may be used, it is to be appreciated that left and right switches, or any other complementary switch orientation, is suitably used. It is to be further appreciated that example embodiments may display alternative switches, such as a SPDT toggle switch, instead.

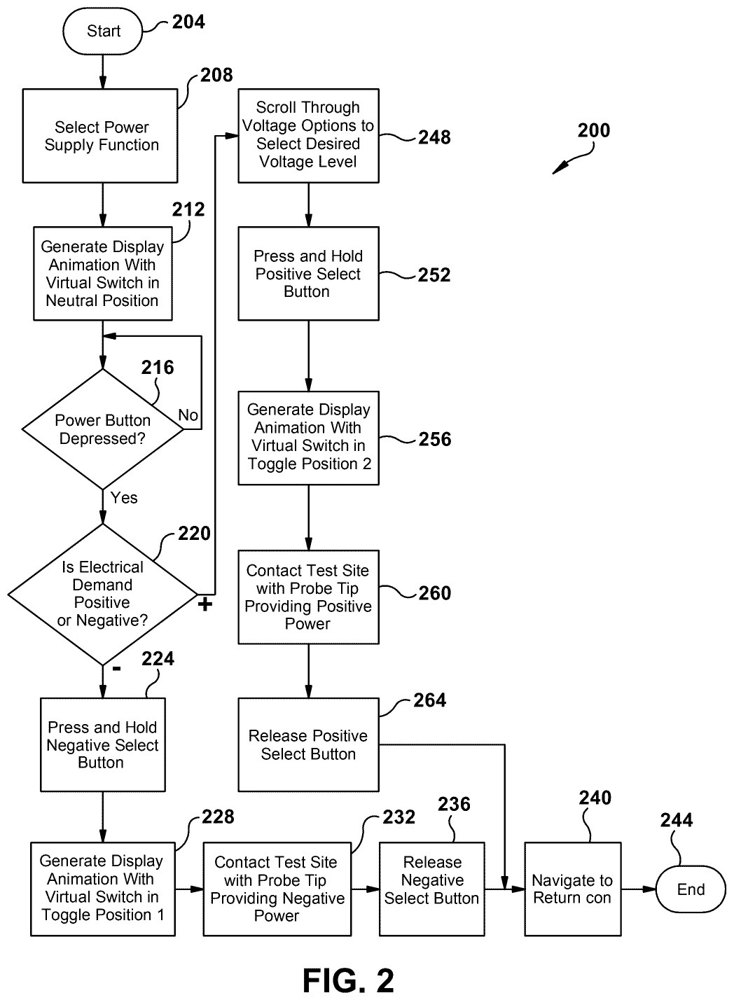

FIG. 2 illustrates a flowchart 200 for an example embodiment of a circuit tester for a power supplying probe with a polarity safeguard. The process commences at block 204 and proceeds to block 208 where a user selects a power supply function on a circuit tester. Next, the tester displays an animation with a virtual switch in a neutral position and block 212. The system proceeds to block 216 where it remains until such time as a negative polarity selection switch or a positive polarity selection switch is activated. If a negative polarity activation switch is activated at block 224, an animation of a virtual switch in a first position is shown on the tester display at block 228. The user then contacts a desired test site with negative power (ground) at block 232 to determine its effect. The user ultimately releases the negative polarity selection switch at block 236, navigates to a return icon on the display at block 240. Once the return icon is selected, such as by depressing the d-pad okay button, where the process ends at block 244.

If a positive voltage is desired for the probe, from block 220, the user navigates to select a desired voltage level option on the display at block 248 and makes their selection, suitably by depressing the OK button on the d-pad. The user then selects the positive polarity selection switch at block 252 and a display animation showing a virtual switch in a second position is shown on the display at block 256. The user then contacts the tip to a desired test site at block 260 and observes the result. The user ultimately releases positive polarity selection switch at block 264, and the process proceeds to block 240 proceeding as described above.

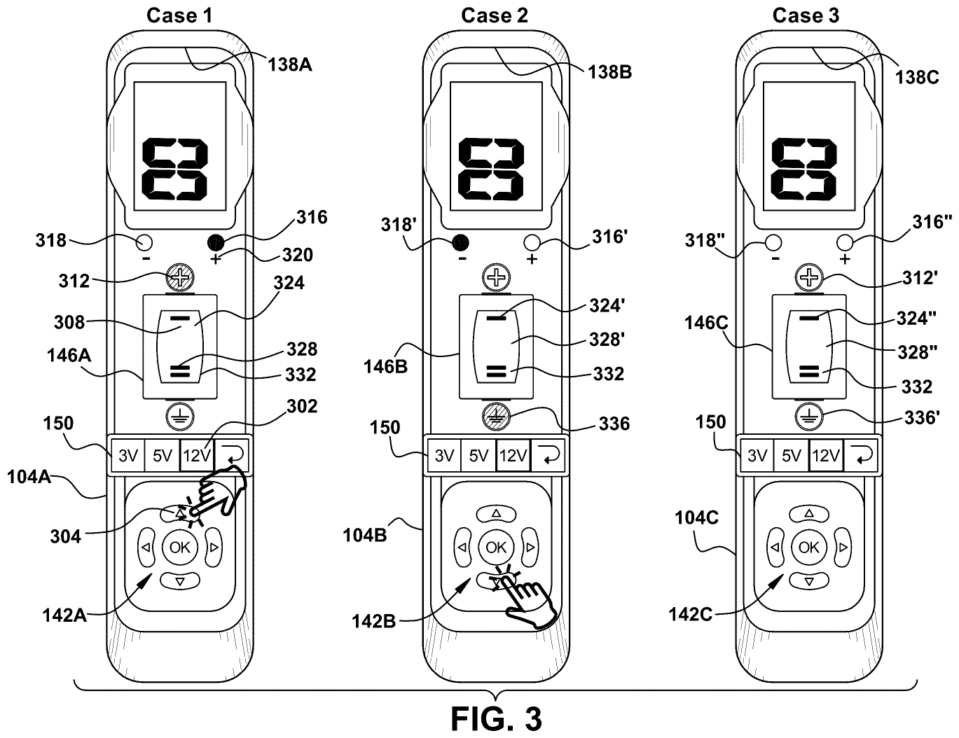

FIG. 3 illustrates example embodiments of a tester having a selectable a circuit tester for a power supplying probe with a polarity safeguard in states of positive polarity (Case 1), a negative polarity (Case 2) and neutral polarity (Case 3). Base unit 104 (FIG. 1) appears as 104A, 104B and 104C in Cases 1-3, respectively. Similarly appearing is a user interface comprising displays 138A, 138B and 138C; d-pad 142A, 142B and 142C; and switch indicia 146A, 146B and 146C. Each display variant further shows user selectable probe tip voltage level selections 150, navigable in conjunction with d-pad 142 when a probe tip is set to a positive polarity (Case 1). Cases 1-3 all indicate a selection of a 12 volt level. However, such selection is only relevant in connection with a Case 1 insofar as the alternative polarities are negative (ground) or neutral.

In Case 1 a positive probe tip polarity is selected by selecting up arrow switch 304 on d-pad 142A. This results in a display of switch indica 146A to appear as if a top portion 308 of the switch is depressed that corresponds with positive polarity selected with up arrow switch 304. Further visual indicia of a positive polarity selection are provided with a highlighted “+” icon 312, highlighted indicator 316 disposed adjacent persistent “+” indicia 320, a non-highlighted indicator adjacent persistent “−” indicia 318, and a highlighted single bar indicia 324 disposed at top portion 308 if switch indica 146A. A complementary double bar indica 328 on bottom portion 332 of switch indica 146A is not highlighted given the selected positive polarity. Thus, a user is provided with multiple visual cues indicative of a selected positive polarity, rendering a strong safeguard against an improper polarity selection during a test operation.

Case 2, wherein a negative probe polarity is select, also includes multiple visual polarity selection cues, including highlighted negative (ground) icon 336, highlighted double bar 328′ at bottom portion 332 of switch indica 146B, and a single bar indica 324′ that is not highlighted.

Case 3, wherein a neutral polarity is selected, illustrates no highlighting of indicia 312′, 316″, 318″, 324″, 328″ or 336′.

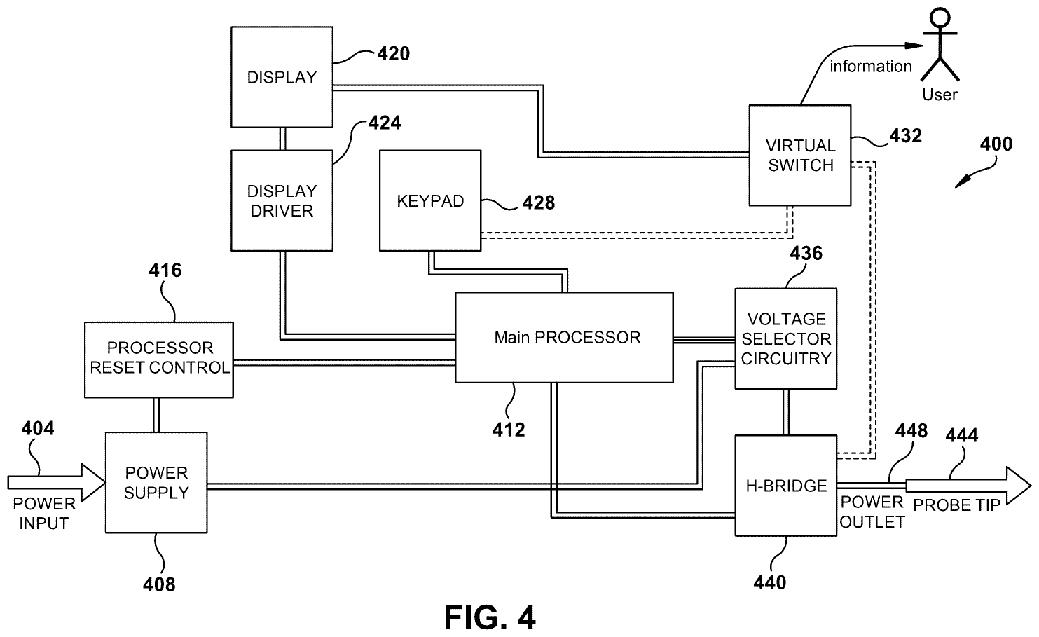

FIG. 4 illustrates a circuit diagram 400 for an example embodiment of a circuit tester for a power supplying probe with a polarity safeguard. In the diagram, power input 404 provides power to power supply 408. Power supply 408, in turn provides power to main processor 412 via processor reset control 416. Processor reset control 416 suitably functions to reset processor 412 in situations such as when positive and negative probe polarities are selected simultaneously by a user causing a short circuit risk which may also trip a circuit breaker or fuse. Processor 412 is in data communication with a user interface comprised of display 420 having an associated display driver 424, and keypad 428, suitably comprised of a d-pad. Processor 412 determines a user polarity selection from keypad 428 and generates corresponding virtual switch indicia 432 on display 420. When a selected polarity is positive, processor 412 initiates a selected voltage level via voltage level selector circuitry 436. Processor 412 sets probe polarity as positive or negative via H-Bridge 440. An H-Bridge is an electronic circuit configuration commonly used to control the direction of current flow to a load. It is named for its typical layout, which resembles the letter “H”. An H-Bridge allows for forward and reverse operation of a load, making it a versatile component in various applications, including motor control, robotics, and automotive systems. A selected voltage (or ground) is relayed from H-Bridge 440 to probe tip 444 via power outlet 448.

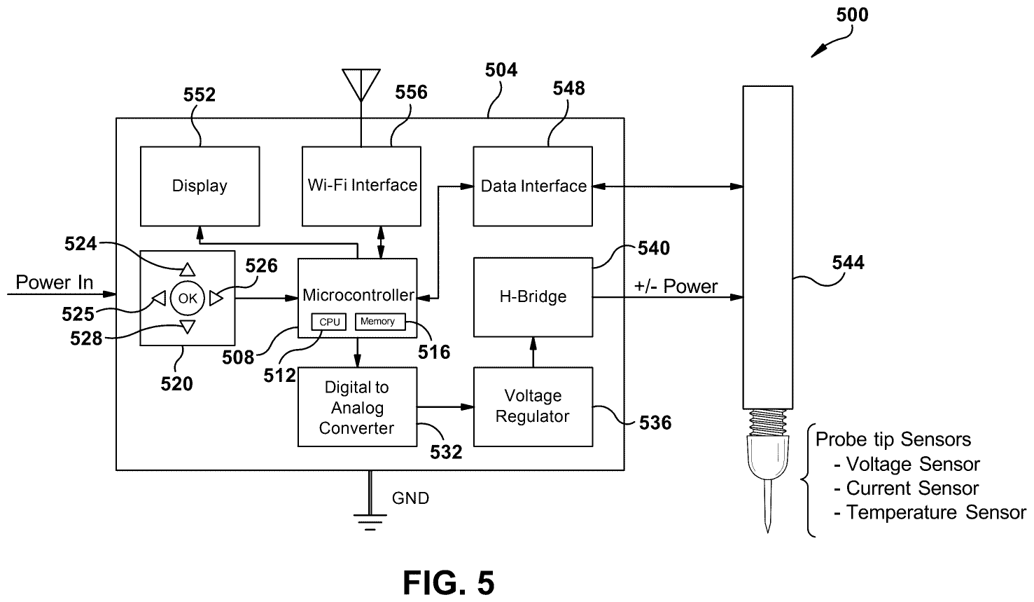

FIG. 5 illustrates another example embodiment of a circuit tester system 500 for a power supplying probe with a polarity safeguard that includes tester unit 504. Tester Unit 504 includes microcontroller 508 which includes processor 512 and memory 516. Microcontroller 516 receives user selections from d-pad 520, including a probe polarity selection. Selection is suitably made by depressing up arrow key 524 for positive voltage application and down arrow key 528 for negative voltage (ground) application. A user selected voltage level (e.g., 3V, 5V or 12V), is suitably selected by a user by scrolling through available voltage level values, each have indicia on the display, by use if left arrow key 525 and right arrow key 526. Microcontroller 508 relays a polarity selection to digital to analog converter 532, which in turn passes the selected polarity to voltage regulator 536, which supplies a selected voltage level when positive polarity is selected. Voltage Regulator 536, in turn, relays the selected voltage level to H-bridge, which then passes the selected voltage to probe 544. Probe 544 includes a voltage sensor, a current sensor and a temperature sensor, digital readings from which are passed back to microcontroller 508 via data interface 548. Switch indica corresponding to a current tip polarity is shown on display 552.

In the example embodiment of FIG. 5, addition circuit protection is afforded by monitoring probe voltage, current and/or temperature. Additionally, probe information is suitably passed to other devices via Wi-Fi interface 556. When an excess voltage level, excess current or excess temperature is detected at the probe, microcontroller 516 can interrupt delivery of power by the probe and provide feedback to the user, suitably including automatically returning the rocker switch image to the neutral position, even though the user may still be selecting their desired polarity via the d-pad.

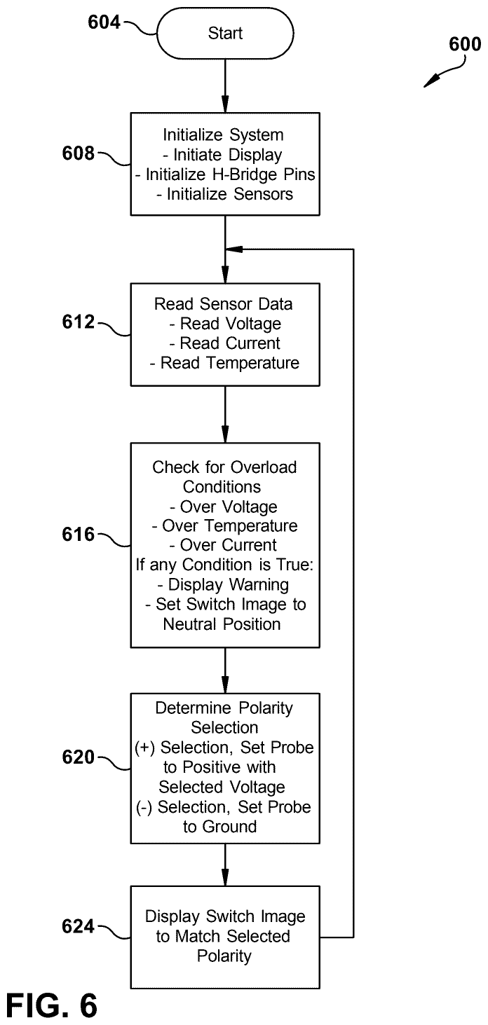

FIG. 6 is a flowchart 600 suitable for operation of microcontroller 508 of FIG. 5. The process commences at block 604 and proceeds to block 608 where the display, H-bridge pins and sensors are initialized. Next, at block 612, voltage, current and temperature levels are read from their associated sensors. Next, at block 616, the microcontroller checks for overload conditions, such as over voltage, over temperature or over current. When one exits, the microcontroller sets the probe tip to neutral and changes the display to show the rocker switch in the neutral position. When no overage condition is present, the system progresses to block 620 where a user's selected polarity is determined and the probe polarity set accordingly. Next, a display of the rocker switch is generated at block 624 to correspond with the current polarity selection.

The particulars shown herein are by way of example only for purposes of illustrative discussion, and are not presented in the cause of providing what is believed to be most useful and readily understood description of the principles and conceptual aspects of the various embodiments of the present disclosure. In this regard, no attempt is made to show any more detail than is necessary for a fundamental understanding of the different features of the various embodiments, the description taken with the drawings making apparent to those skilled in the art how these may be implemented in practice.

What is claimed is:

1. A power supply probe with a voltage polarity safeguard comprising:
a user interface including a plurality of control switches including a negative polarity selection switch and a positive polarity selection switch, and an image display;
a power input configured to receive electrical power from an associated power source; and
a processor and associated memory, the processor configured to
receive a polarity selection signal from an associated user corresponding to an engagement of one of the negative polarity switch or the positive polarity switch,
initiate application, on an associated probe tip, of a probe voltage having a selected polarity associated with a received polarity selection signal, and
show an image corresponding to a rocker switch on the display, the image comprising the rocker switch in a first or second position in accordance with a value of the selected polarity.

2. The power supply probe with a voltage polarity safeguard of claim 1 wherein the user interface includes a d-pad, wherein the negative polarity switch and the positive polarity switch are on opposed directional controls on the d-pad.

3. The power supply probe with a voltage polarity safeguard of claim 2 wherein an alignment of the opposed directional controls corresponds to an alignment of an actuation axis of the rocker switch image.

4. The power supply probe with voltage polarity safeguard of claim 3 wherein the processor is further configured to terminate voltage application on the probe tip when no polarity selection switch is engaged.

5. The power supply probe with a voltage polarity safeguard of claim 4 wherein, to set a probe voltage level, the processor is further configured to
show selectable indicia on the display corresponding to a plurality of different voltage levels,
receive user navigation input via the d-pad to a selected one of the selectable indica, and
initiate the application of the probe voltage with a voltage level corresponding to the selected indicia.

6. The power supply probe with a voltage polarity safeguard of claim 5 wherein the processor is further configured to limit setting a probe voltage level to when the selected polarity is positive.

7. The power supply probe with a voltage polarity safeguard of claim 6 wherein the processor is further configured to set a probe tip to a neutral level when the positive polarity selection switch and the negative polarity selection switch are engaged concurrently.

8. A method for safeguarded selection of test probe polarity comprising:
receiving a polarity selection signal from an associated user corresponding to an engagement by the user of one of a negative polarity switch or a positive polarity switch included on a user interface of a circuit tester;
initiating application, on an associated probe tip, of a probe voltage having a selected polarity associated with a received polarity selection signal; and
showing an image corresponding to a rocker switch on a circuit tester display, the image comprising the rocker switch in a first or second position in accordance with a value of the selected polarity.

9. The method for safeguarded selection of test probe polarity of claim 8 wherein the user interface includes a d-pad, wherein the negative polarity switch and the positive polarity switch are on opposed directional controls on the d-pad.

10. The method for safeguarded selection of test probe polarity of claim 9 wherein an alignment of the opposed directional controls corresponds to an alignment of an actuation axis of the rocker switch image.

11. The method for safeguarded selection of test probe polarity of claim 10 further comprising terminating voltage application on the probe tip when no polarity selection switch is engaged.

12. The method for safeguarded selection of test probe polarity of claim 11 further comprising:
showing selectable indicia on the display corresponding to a plurality of different voltage levels;
receiving user navigation input via the d-pad to a selected one of the selectable indica; and
initiating the application of the probe voltage with a voltage level corresponding to the selected indicia.

13. The method for safeguarded selection of test probe polarity of claim 12 further comprising limiting setting a probe voltage level to when the selected polarity is positive.

14. The method for safeguarded selection of test probe polarity of claim 13 further comprising setting a probe tip to a neutral level when the positive polarity selection switch and the negative polarity selection switch are engaged concurrently.

15. A non-transitory computer readable storage medium storing a program for causing a computer to execute a control method for safeguarded selection of test probe polarity, the method comprising:
receiving a polarity selection signal from an associated user corresponding to an engagement by the user of one of a negative polarity switch or a positive polarity switch included on a user interface of a circuit tester;
initiating application, on an associated probe tip, of a probe voltage having a selected polarity associated with a received polarity selection signal; and
showing an image corresponding to a rocker switch on a circuit tester display, the image comprising the rocker switch in a first or second position in accordance with a value of the selected polarity.

16. The non-transitory computer readable storage medium storing a program for causing a computer to execute a control method for safeguarded selection of test probe polarity of claim 15 wherein the user interface includes a d-pad, wherein the negative polarity switch and the positive polarity switch are on opposed directional controls on the d-pad.

17. The non-transitory computer readable storage medium storing a program for causing a computer to execute a control method for safeguarded selection of test probe polarity of claim 16 wherein an alignment of the opposed directional controls corresponds to an alignment of an actuation axis of the rocker switch image.

18. The non-transitory computer readable storage medium storing a program for causing a computer to execute a control method for safeguarded selection of test probe of claim 17, wherein the method further comprises terminating voltage application on the probe tip when no polarity selection switch is engaged.

19. The non-transitory computer readable storage medium storing a program for causing a computer to execute a control method for safeguarded selection of test probe of claim 18, wherein the method further comprises:
showing selectable indicia on the display corresponding to a plurality of different voltage levels;
receiving user navigation input via the d-pad to a selected one of the selectable indica; and
initiating the application of the probe voltage with a voltage level corresponding to the selected indicia.

20. The non-transitory computer readable storage medium storing a program for causing a computer to execute a control method for safeguarded selection of test probe of claim 19 wherein the method further comprises setting a probe tip to a neutral level when the positive polarity selection switch and the negative polarity selection switch are engaged concurrently.
